(19) United States
(12) Patent Application Publication
(10) Pub. No.: US 2017/0212153 A1
(43) Pub. Date: Jul. 27, 2017

(54) CURRENT DETECTING DEVICE

(71) Applicant: STANLEY ELECTRIC CO., LTD., Tokyo (JP)

(72) Inventors: Satoshi TSUJIMOTO, Tokyo (JP); Masami TAIMA, Tokyo (JP)

(73) Assignee: STANLEY ELECTRIC CO., LTD., Tokyo (JP)

(21) Appl. No.: 15/410,124

(22) Filed: Jan. 19, 2017

(30) Foreign Application Priority Data
Jan. 22, 2016 (JP) 2016-010582

(51) Int. Cl. G01R 19/00

(52) U.S. Cl. CPC G01R 19/0092

(57) ABSTRACT

To provide a current detecting device capable of reducing lowering of responsiveness and variations in responsiveness among the phases. The current detecting device includes a plurality of bus bars that extend in the same direction and parallel to one another and are disposed at fixed intervals in the width direction of the bus bars, a plurality of current sensors disposed corresponding to the plurality of bus bars respectively, and a plurality of output terminals disposed corresponding to the plurality of bus bars respectively and wherein each output terminal is connected to one of the plurality of current sensors wherein the plurality of output terminals are disposed so that the distances between each of the output terminals and the corresponding bus bar are substantially constant.

### BACKGROUND OF THE INVENTION

### Field of the Invention

The present invention relates to a current detecting device using Hall elements and the like.

### Description of the Background Art

A prior art related to a current detecting device using Hall elements and the like such as Japanese Unexamined Patent Application Publication No. 2013-15358 (hereinafter referred to as “Patent document 1”), for example, discloses a current sensor comprising a magnetic sensor IC which includes a plurality of terminals, a plurality of sensor units in each of which the magnetic sensor IC and a core are integrated, a main body including lead frames as a plurality of wiring items electrically connecting the sensor units, and a supporting section which is provided in the main body and supports the sensor unit.

In regard to the current sensor disclosed in Patent document 1, since the connector terminal is disposed sufficiently distant from each of the sensor units, the influence of magnetic noise and the like to the connector terminal is considered to be limited. However, in case where miniaturizing a current detecting device is being considered, when the connector terminal is disposed close to the sensor units, lowering of responsiveness due to the influence of magnetic noise to the connector terminal cannot be ignored.

Further, in regard to a current detecting device in general, depending on the disposition of each of the connector terminals corresponding to a plurality of magnetic sensors, the difference in the distance between each of the bus bars and the connector terminals occurs, thereby causing variations in responsiveness among the phases.

It is therefore an object of specific aspects according to the present invention to provide a current detecting device capable of reducing lowering of responsiveness and variations in responsiveness among the phases.

### SUMMARY OF THE INVENTION

A current detecting device according to an aspect of the present invention includes (a) a plurality of bus bars that extend in the same direction and parallel to one another and are disposed at fixed intervals in the width direction of said bus bars, (b) a plurality of current sensors disposed corresponding to the plurality of bus bars respectively, and (c) a plurality of output terminals disposed corresponding to the plurality of bus bars respectively and wherein each output terminal is connected to one of the plurality of current sensors, (d) wherein the plurality of output terminals are disposed so that the distances between each of the output terminals and the corresponding bus bar are substantially constant.

According to the configuration described above, an equal positional relationship between each of the output terminals and the corresponding bus bar is achieved, thereby reducing deterioration of responsiveness and variations in responsiveness among the phases of the current detecting device.

In the current detecting device described above, the distance between the output terminal and the corresponding bus bar may be the shortest distance between the substantial center in the width direction of each of the plurality of the bus bars and one of the output terminals corresponding to the plurality of output terminals. Further, preferably, the plurality of output terminals are disposed at the same height position based on a predetermined position. Further, preferably, the plurality of output terminals are disposed at the position where no output terminals overlap with the bus bars in the thickness direction of the plurality of bus bars. Further, preferably, the plurality of bus bars are formed into the same shape, and are disposed parallel to one another in the extending direction so as to share the same height position based on a predetermined position.

### BRIEF DESCRIPTION OF THE DRAWINGS

FIG. 1 is a perspective view illustrating a configuration of a current detecting device of one embodiment.

FIG. 2 is a plan view (a front view) illustrating a configuration of a current detecting device of one embodiment.

FIG. 3 is a perspective view illustrating a configuration of a current detecting device of another embodiment.

FIG. 4 is a plan view (a front view) illustrating a configuration of a current detecting device of another embodiment.

### DESCRIPTION OF THE PREFERRED EMBODIMENTS

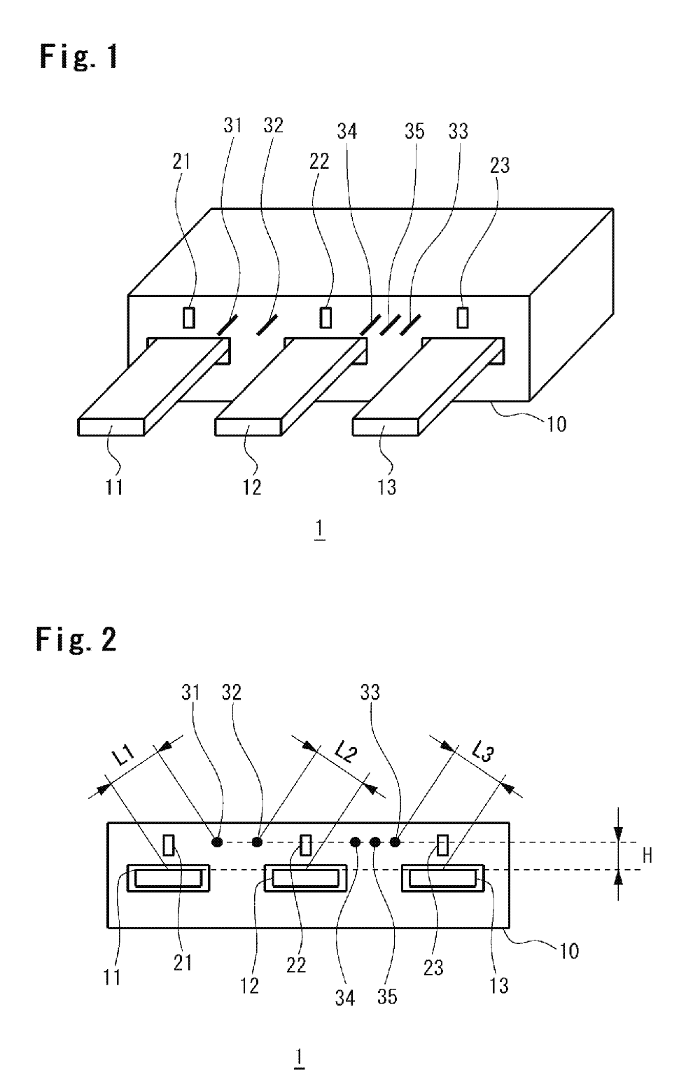

FIG. 1 is a perspective view illustrating a configuration of a current detecting device of one embodiment. And FIG. 2 is a plan view (a front view) illustrating a configuration of this current detecting device. The current detecting device shown in each figure includes a plurality of bus bars 11, 12, 13 (three in this embodiment), a plurality of Hall ICs 21, 22, 23 (three in this embodiment) disposed in one-to-one correspondence with each of the bus bars 11, etc., a plurality of output terminals 31, 32, 33 (three in this embodiment), a power terminal 34, and a reference potential terminal 35 (GND). Each of the bus bars 11, etc., Hall ICs 21, etc., and output terminals 31, etc., are integrated by a resin member, for example.

Through each of the bus bars 11, etc., electric current to be measured flows. In this embodiment, each of the bus bars 11, 12, 13 is a flat-plate shaped conductor formed identically extending in the same direction and parallel to one another. As shown in FIG. 2, each of the bus bars 11, 12, 13 is disposed so as to share the same height from the bottom surface 10 of current detecting device 1, parallel to one another in the extending direction, and further, disposed at fixed intervals in the width direction. These bus bars 11, etc. are disposed at the openings provided in the (resin-made) casing of current detecting device 1.

Each of Hall ICs 21, 22, 23 is disposed in correspondence with each of bus bars 11, 12, 13. In this embodiment, Hall IC 21 is disposed apart from bus bar 11, on the upper side in the thickness direction (in the vertical direction in the figure) of bus bar 11, and by detecting the strength of a magnetic field of the electric current flowing through this bus bar 11, the magnitude of the electric current is measured. Hall IC 22 is disposed apart from bus bar 12, on the upper side in the thickness direction of bus bar 12, and by detecting the strength of a magnetic field of the electric current flowing through this bus bar 12, the magnitude of the electric current is measured. Hall IC 23 is disposed apart from bus bar 13, on the upper side in the thickness direction of bus bar 13, and by detecting the strength of a magnetic field of the electric current flowing through this bus bar 13, the magnitude of the electric current is measured. In this embodiment, each of Hall ICs 21, 22, 23 is disposed to overlap with the substantial center in the width direction of each of bus bars 11, 12, 13, respectively. Thus, the positional relationship between each of Hall ICs 21, etc. and each of bus bars 11, etc. where the each Hall IC and each bus bar is paired respectively, becomes equal.

Each of output terminals 31, 32, 33 is a bar-shaped (line-shaped) conductor disposed in correspondence with each of bus bars 11, 12, 13. As shown in FIG. 2, in this embodiment, output terminal 31 is disposed obliquely upward to the right of bus bar 11 and externally transmits an electric signal output from Hall IC 21. Further, output terminal 32 is disposed obliquely upward to the left of bus bar 12 and externally transmits an electric signal output from Hall IC 22. Further, output terminal 33 is disposed obliquely upward to the left of bus bar 13 and externally transmits an electric signal output from Hall IC 23.

As shown in FIG. 2, all output terminals 31, 32, 33 are disposed at the same height H taking the upper surface of a each of bus bars 11, etc. as a reference. Output terminal 31 is arranged in between the upper region of bus bar 11 and bus bar 12, disposed closer to bus bar 11. Output terminal 32 is arranged in between the upper region of bus bar 11 and bus bar 12, disposed closer to bus bar 12. Output terminal 33 is arranged in between the upper region of bus bar 12 and bus bar 13, disposed closer to bus bar 13. That is, each of output terminals 31, etc. is disposed so that none of them overlaps with each of bus bars 11, etc. in their thickness direction.

Further, when the distance between each of output terminals 31, etc. and each of bus bars 11, 12, 13 are defined as L1, L2, L3 respectively (refer to FIG. 2), each of output terminals 31, 32, 33 is disposed so that the distances L1, L2, L3 are substantially equal (substantially constant).

By disposing each of output terminals 31, etc. close to each of bus bars 11, etc. respectively (phases to be measured), the responsiveness can be improved. Specifically, when noise is induced near output terminals 31, etc., responsiveness improves (responsiveness is quickened), thereby compensating for the lowering of responsiveness (delay in response) due to the noise induced to power terminal 34.

Further, by arranging each of output terminals 31, etc. in the same distance and position from each of bus bars 11, etc. respectively, the variation among each of the the bus bars (among phases to be measured) can be reduced.

In this embodiment, although the distances L1, L2, L3 are defined as the shortest distance between the upper surface and in the center in the width direction of each of bus bars 11, 12, 13, and each of output terminals 31, 32, 33, respectively (refer to FIG. 2), the definition of the above stated distances L1, L2, L3 are not limited thereto. Since only the positional relationship between each of bus bars 11, etc. and each of output terminals 31, etc. respectively need be equal, the distances L1, L2, L3 may be defined as the distance referenced from one end of the upper surface of each of bus bars 11, etc., for example.

Power terminal 34 and reference potential terminal 35 (GND) are both disposed at the same height H taking the upper surface of a each of bus bars 11, etc. as a reference. That is, they are disposed at the same height as each of output terminals 31, 32, 33. Power terminal 34 and reference potential terminal 35 (GND) are both disposed arranged in between the upper region of bus bar 12 and bus bar 13, power terminal 34 being disposed closer to bus bar 12, and reference potential terminal 35 being disposed closer to bus bar 13.

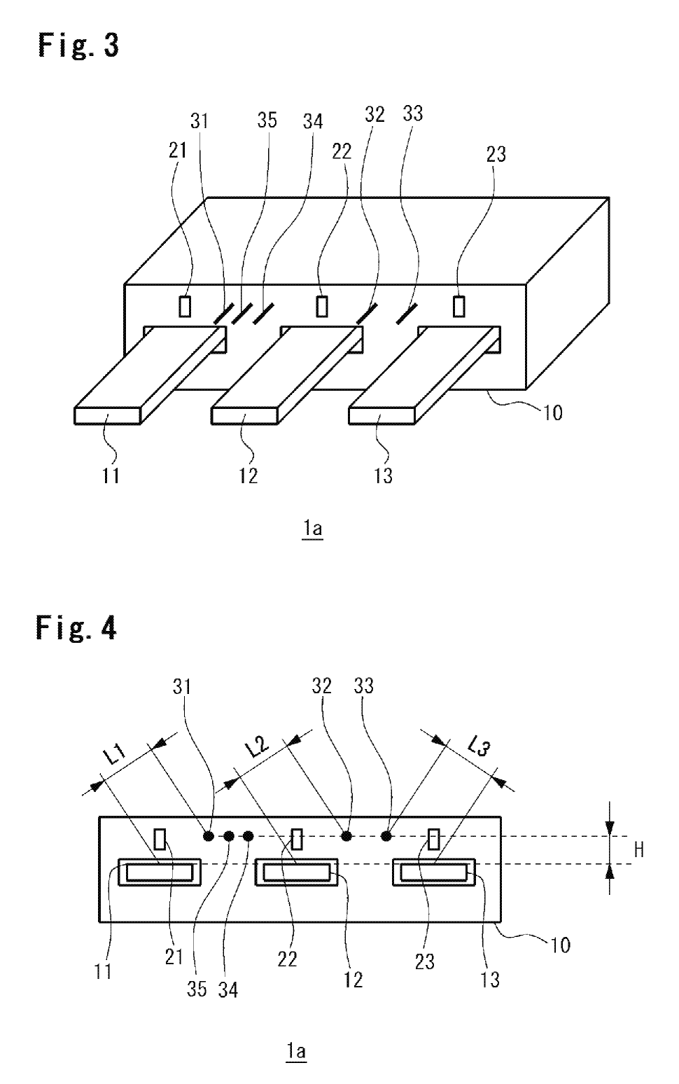

FIG. 3 is a perspective view illustrating a configuration of a current detecting device of another embodiment. And FIG. 4 is a plan view (a front view) illustrating a configuration of this current detecting device. The current detecting device shown in FIG. 3 and FIG. 4 basically has the same structure as the device shown in FIG. 1 and FIG. 2, and the only difference is that the arrangement of output terminal 32, power terminal 34, and reference potential terminal 35 are transposed. Therefore, in the following, detailed descriptions of the components common to both embodiments are omitted and are denoted by the same reference numbers. Only the different components will be described.

In this embodiment la, output terminal 32 is disposed obliquely upward to the right of bus bar 12 and externally transmits an electric signal output from Hall IC 22. Power terminal 34 and reference potential terminal 35 (GND) are both disposed arranged in between the upper region of bus bar 11 and bus bar 12, power terminal 34 being disposed closer to bus bar 12, and reference potential terminal 35 being disposed closer to bus bar 11.

According to the embodiments described above, it is possible to reduce lowering of responsiveness and variations in responsiveness among the phases of the current detecting device.

Note that this invention is not limited to the subject matter of the foregoing embodiments, and can be implemented by being variously modified within the scope of the gist of the present invention. For example, in the above-described embodiments, as an example of current sensors, although Hall ICs using Hall element(s) are introduced, sensors using devices such as Magneto Resistive Device may also be used.

What is claimed is:

1. An current detecting device comprising:
a plurality of bus bars that extend in the same direction and parallel o one another and are disposed at fixed intervals in the width direction of said bus bars,
a plurality of current sensors disposed corresponding to the plurality of bus bars respectively, and
a plurality of output terminals disposed corresponding to the plurality of bus bars respectively and wherein each output terminal is connected to one of the plurality of current sensors; wherein:
the plurality of output terminals are disposed so that the distances between each of the output terminals and the corresponding bus bar are substantially constant.

2. The current detecting device according to claim 1, wherein:
the distance between the output terminal and the corresponding bus bar is the shortest distance between the substantial center in the width direction of each of the plurality of the bus bars and one of the output terminals corresponding to the plurality of output terminals.

3. The current detecting device according to claim 1, wherein:
the plurality of output terminals are disposed at the same height position based on a predetermined position.

4. The current detecting device according to claim 2, wherein:
the plurality of output terminals are disposed at the same height position based on a predetermined position.

5. The current detecting device according to claim 1, wherein:
the plurality of output terminals are disposed at the position where no output terminals overlap with the bus bars in the thickness direction of the plurality of bus bars.

6. The current detecting device according to claim 2, wherein:
the plurality of output terminals are disposed at the position where no output terminals overlap with the bus bars in the thickness direction of the plurality of bus bars.

7. The current detecting device according to claim 3, wherein:
the plurality of output terminals are disposed at the position where no output terminals overlap with the bus bars in the thickness direction of the plurality of bus bars.

8. The current detecting device according to claim 4, wherein:
the plurality of output terminals are disposed at the position where no output terminals overlap with the bus bars in the thickness direction of the plurality of bus bars.

9. The current detecting device according to claim 1, wherein:
the plurality of bus bars are formed into the same shape, and are disposed parallel to one another in the extending direction so as to share the the same height position based on a predetermined position.

10. The current detecting device according to claim 2, wherein:
the plurality of bus bars are formed into the same shape, and are disposed parallel to one another in the extending direction so as to share the the same height position based on a predetermined position.

11. The current detecting device according to claim 3, wherein:
the plurality of bus bars are formed into the same shape, and are disposed parallel to one another in the extending direction so as to share the the same height position based on a predetermined position.

12. The current detecting device according to claim 4, wherein:
the plurality of bus bars are formed into the same shape, and are disposed parallel to one another in the extending direction so as to share the the same height position based on a predetermined position.

13. The current detecting device according to claim 5, wherein:
the plurality of bus bars are formed into the same shape, and are disposed parallel to one another in the extending direction so as to share the the same height position based on a predetermined position.

14. The current detecting device according to claim 6, wherein:
the plurality of bus bars are formed into the same shape, and are disposed parallel to one another in the extending direction so as to share the the same height position based on a predetermined position.

15. The current detecting device according to claim 7, wherein:
the plurality of bus bars are formed into the same shape, and are disposed parallel to one another in the extending direction so as to share the the same height position based on a predetermined position.

16. The current detecting device according to claim 8, wherein:
the plurality of bus bars are formed into the same shape, and are disposed parallel to one another in the extending direction so as to share the the same height position based on a predetermined position.
